(19) United States
(12) Patent Application Publication
(10) Pub. No.: US 2023/0135187 A1
(43) Pub. Date: May 4, 2023

(54) SEMICONDUCTOR DEVICE, METHOD OF MANUFACTURING THE SAME, AND ELECTRONIC APPARATUS INCLUDING THE SAME

(71) Applicant: INSTITUTE OF MICROELECTRONICS, CHINESE ACADEMY OF SCIENCES, Beijing (CN)

(72) Inventor: Huilong Zhu, Poughkeepsie, NY (US)

(21) Appl. No.: 17/995,698

(22) PCT Filed: Mar. 10, 2021
(86) PCT No.: PCT/CN2021/079982

§ 371 Date: Oct. 6, 2022

(30) Foreign Application Priority Data
Apr. 10, 2020 (CN) 202010282958.X

(51) Int. Cl. H01L 29/06; H01L 29/08; H01L 29/66; H01L 29/786; H01L 29/775; H01L 27/092; H01L 21/8238

(52) U.S. Cl. CPC H01L 29/0673; H01L 29/0847; H01L 29/6656; H01L 29/78696; H01L 29/775; H01L 29/66439; H01L 27/0924; H01L 21/823807; H01L 21/823814; H01L 21/823864; H01L 29/66545

(57) ABSTRACT

Provided are a semiconductor device, a method of manufacturing the semiconductor device, and an electronic apparatus including the semiconductor device. According to the embodiments, the semiconductor device may include: a nanosheet stack layer on a substrate including a plurality of nanosheets spaced apart from each other in a vertical direction relative to the substrate, wherein at least one of the plurality of nanosheets includes a first portion in a first orientation, and at least one of an upper surface and a lower surface of the first portion is not parallel to a horizontal surface of the substrate.

### CROSS REFERENCE TO RELATED APPLICATION(S)

This application is a Section 371 National Stage Application of International Application No. PCT/CN2021/079982 filed on Mar. 10, 2021, which claims priority to Chinese patent Application No. CN202010282958.X entitled “semiconductor device, method of manufacturing the same, and electronic apparatus including the same” filed on Apr. 10, 2020, the content of which are incorporated herein by reference in their entirety.

### TECHNICAL FIELD

The present disclosure relates to a field of semiconductors, and in particular to a semiconductor device, a method of manufacturing a semiconductor device, and an electronic apparatus including the semiconductor device.

### BACKGROUND

Various different structures are proposed to meet a challenge of further miniaturization of semiconductor devices, such as a Fin Field Effect Transistor (FinFET) and a Multi-Bridge Channel Field Effect Transistor (MBCFET). For the FinFET, a further miniaturization is limited. The MBCFET has a prospect, however, a performance and an integration of the MBCFET is required to be further enhanced.

### SUMMARY

In view of this, an object of the present disclosure is, at least in part, to provide a semiconductor device, a method of manufacturing the semiconductor device, and an electronic apparatus including the semiconductor device, so as to optimize a device performance by changing an orientation of a semiconductor surface.

According to an aspect of the present disclosure, there is provided a semiconductor device including: a nanosheet stack layer on a substrate including a plurality of nanosheets spaced apart from each other in a vertical direction relative to the substrate, wherein at least one of the plurality of nanosheets includes a first portion in a first orientation, and at least one of an upper surface and a lower surface of the first portion is not parallel to a horizontal surface of the substrate.

According to another aspect of the present disclosure, there is provided a semiconductor device, including: a first device and a second device on a substrate, wherein the first device includes a plurality of first nanosheets stacked and spaced apart from each other in a vertical direction relative to the substrate, and the second device includes a plurality of second nanosheets stacked and spaced apart from each other in the vertical direction relative to the substrate, wherein at least one of the first nanosheets includes a first portion in a first orientation, and at least one of the second nanosheets includes a second portion in a second orientation different from the first orientation.

According to another aspect of the present disclosure, there is provided a method of manufacturing a semiconductor device, including: forming a pattern on a substrate, wherein the pattern includes at least a first surface in a first orientation, wherein the first surface is not parallel to a horizontal surface of the substrate; and forming a stack layer of alternately arranged sacrificial layers and channel layers on the substrate having the pattern, wherein at least a portion of at least one of an upper surface and a lower surface of at least one of the channel layers is in the first orientation.

According to another aspect of the present disclosure, there is provided an electronic apparatus including the above-mentioned semiconductor device.

According to the embodiments of the present disclosure, the semiconductor device may have a structure that is not parallel to the horizontal surface of the substrate. With surfaces in different orientations, performance adjustment and optimization may be achieved. For example, the structure may be used in a channel to optimize a carrier mobility. In a case where the structure is used as a channel, the semiconductor device may be a Multi-Bridge Channel Field Effect Transistor (MBCFET). In addition, the channel may have a zigzag or wavy shape, so that a Multi-Wave Bridge Channel Field Effect Transistor (MWCFET) may be obtained.

### BRIEF DESCRIPTION OF THE DRAWINGS

The above and other objectives, features, and advantages of the present disclosure will be clearer through the following descriptions of embodiments of the present disclosure with reference to the accompanying drawings, in which:

FIG. 1 to FIG. 20(b) show schematic diagrams of some stages in a process of manufacturing a semiconductor device according to an embodiment of the present disclosure;

FIG. 21 shows a schematic diagram of a configuration of a Complementary Metal-Oxide-Semiconductor (CMOS) according to an embodiment of the present disclosure;

FIG. 22 to FIG. 30 show schematic diagrams of some stages in a process of manufacturing a semiconductor device according to another embodiment of the present disclosure, in which

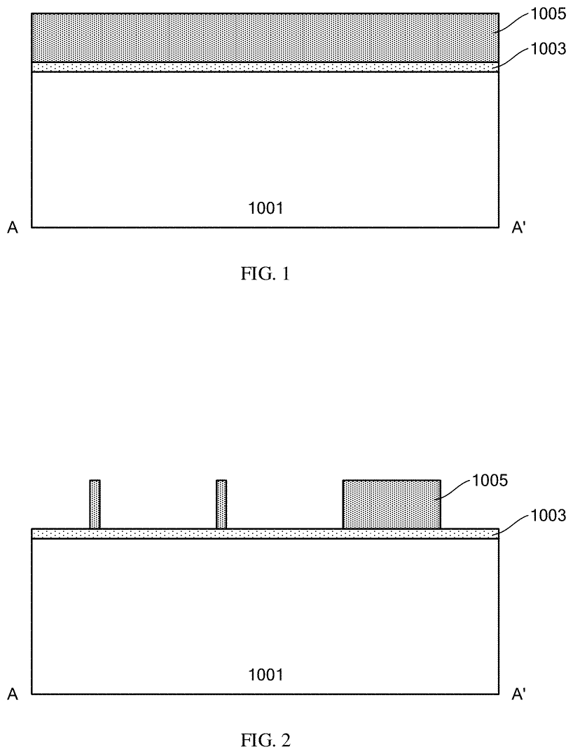

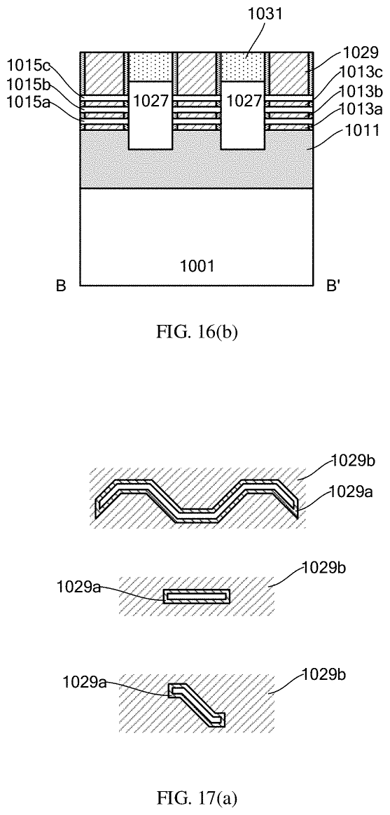

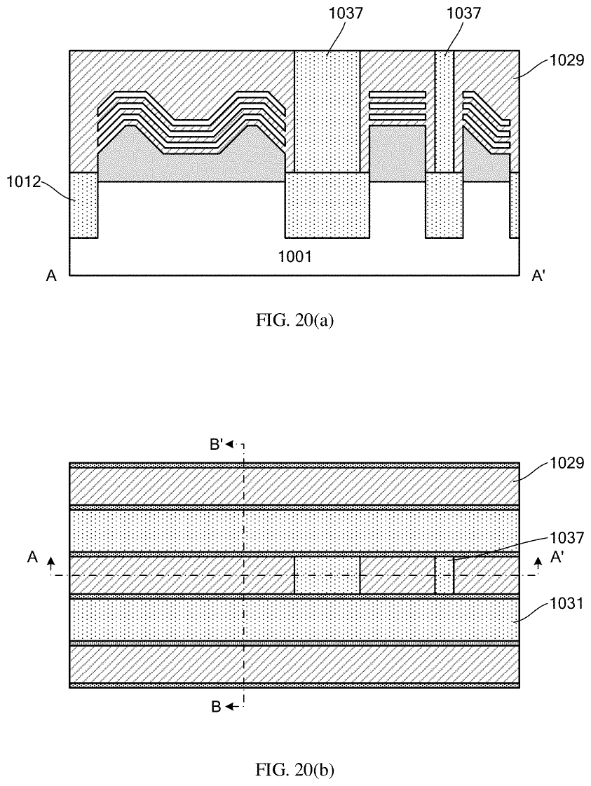

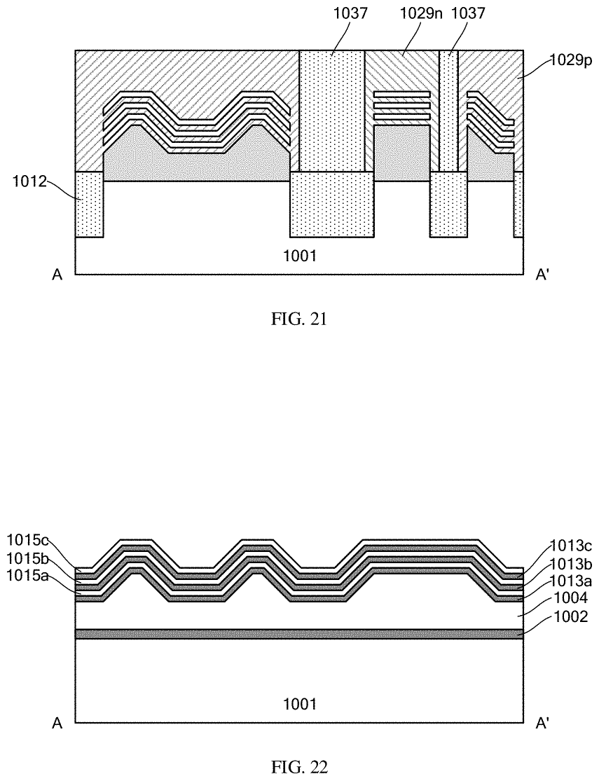

FIG. 1 to FIG. 11, FIG. 12(a), FIG. 16(a), FIG. 20(a), and FIG. 21 to FIG. 30 are cross-sectional views taken along line AA′;

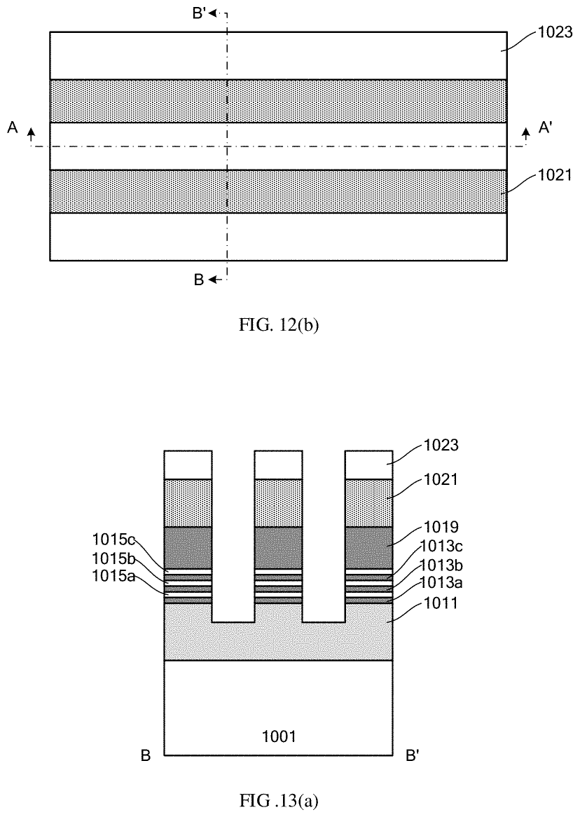

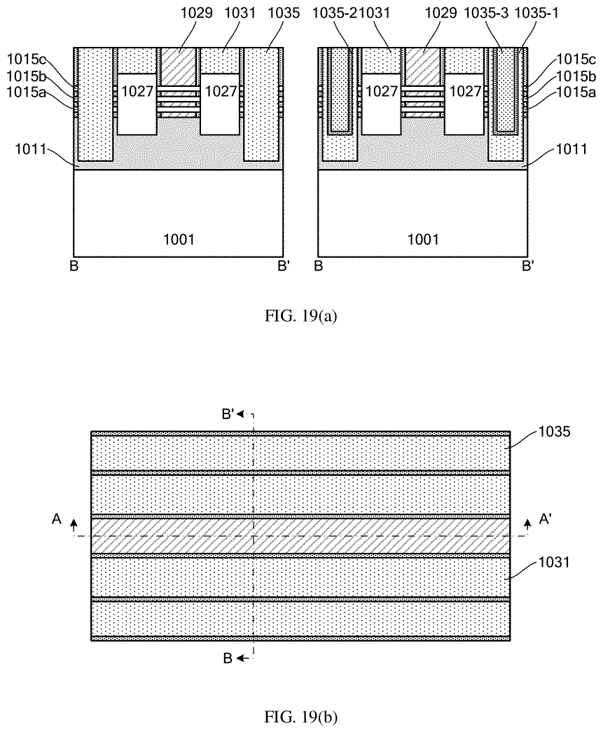

FIG. 12(b), FIG. 13(b), FIG. 19(b) and FIG. 20(b) are top views, and positions of line AA′ and line BB′ are shown in the top views;

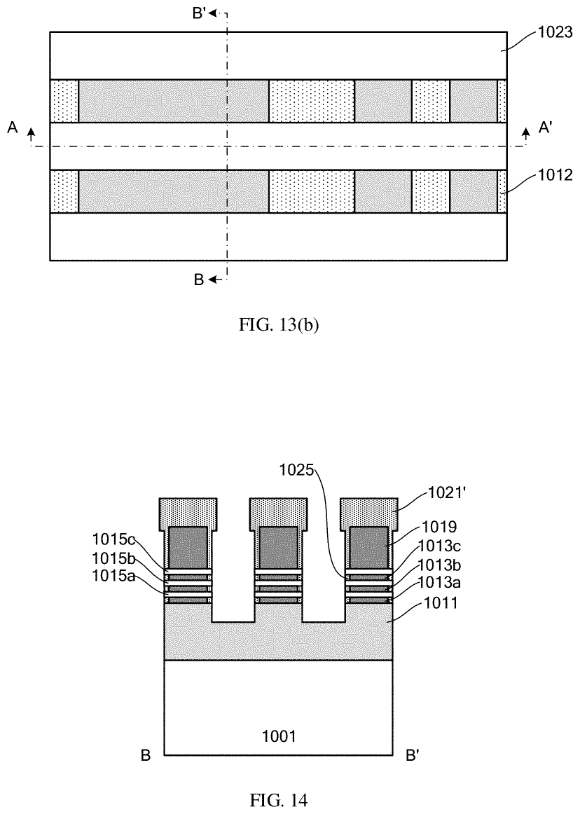

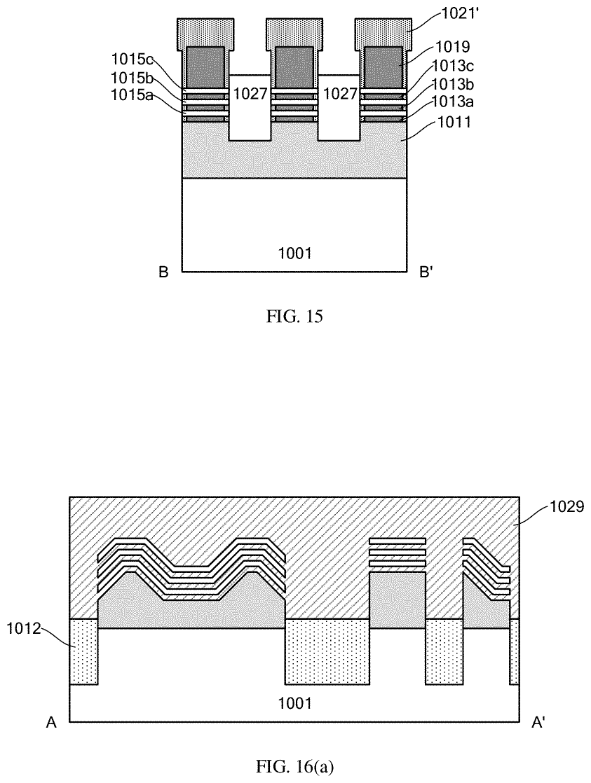

FIG. 13(a), FIG. 14, FIG. 15, FIG. 16(b), FIG. 18, and FIG. 19(a) are cross-sectional views taken along line BB′;

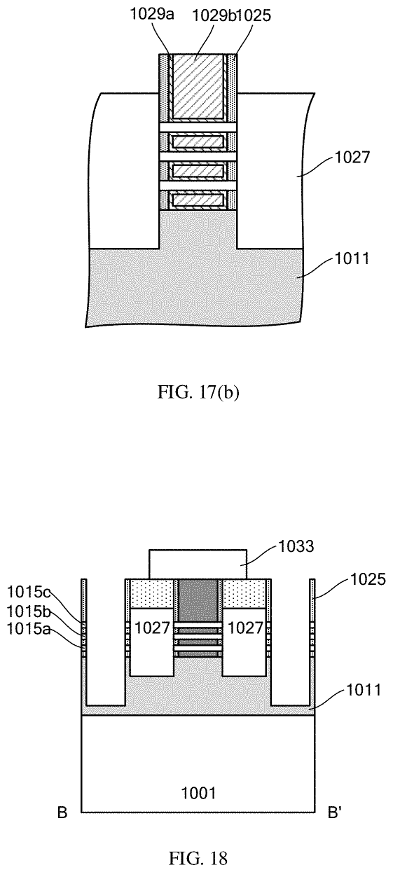

FIG. 17(a) and FIG. 17(b) are enlarged views of gate stack portions around a channel layer.

Throughout the accompanying drawings, the same or similar reference numerals indicate the same or similar components.

### DETAILED DESCRIPTION OF EMBODIMENTS

Embodiments of the present disclosure will be described below with reference to the accompanying drawings. It should be understood, however, that these descriptions are merely exemplary and are not intended to limit the scope of the present disclosure. In addition, in the following descriptions, descriptions of well-known structures and technologies are omitted to avoid unnecessarily obscuring the concept of the present disclosure.

Various schematic structural diagrams according to embodiments of the present disclosure are shown in the accompanying drawings. The drawings are not drawn to scale. Some details are enlarged and some details may be omitted for clarity of presentation. Shapes of the various regions, layers as well as a relative size and a positional relationship thereof shown in the drawings are only exemplary. In practice, there may be deviations due to manufacturing tolerances or technical limitations, and those skilled in the art may additionally design regions/layers with different shapes, sizes, and relative positions according to actual needs.

In the context of the present disclosure, when a layer/element is referred to as being located “on” another layer/element, the layer/element may be directly on the another layer/element, or there may be an intermediate layer/element therebetween. In addition, if a layer/element is located “on” another layer/element in one orientation, the layer/element may be located “under” the another layer/element when the orientation is reversed.

According to the embodiments of the present disclosure, a semiconductor device is provided. The semiconductor device may include a stack layer of a plurality of nanosheets spaced apart from each other in a vertical direction (e.g., a direction perpendicular to a horizontal surface of a substrate) relative to the substrate. The nanosheet may be inclined relative to the vertical direction, e.g., extending in a lateral direction (or in a direction deviating from the lateral direction within a certain range) relative to the substrate. According to the embodiments of the present disclosure, at least one nanosheet may include a first portion in a first orientation, and at least one of an upper surface and a lower surface of the first portion may not be parallel to a horizontal surface of the substrate. By adjusting the first orientation, a device performance such as a carrier mobility may be optimized. For example, the horizontal surface of the substrate may be one of {100} crystal plane families, and at least one of the upper surface and the lower surface of the first portion may be one of {110} crystal plane families, which is beneficial to a hole mobility. Thus, a configuration according to the embodiments of the present disclosure is beneficial to improve the device performance when a p-type device is formed on a (100) substrate. Alternatively, the horizontal surface of the substrate may be one of the {110} crystal plane families, and at least one of the upper surface and the lower surface of the first portion may be one of the {100} crystal plane families, which is beneficial to an electron mobility. Thus, a configuration according to the embodiments of the present disclosure is beneficial to improve the device performance when an n-type device is formed on a (110) substrate.

According to the embodiments of the present disclosure, in addition to the first portion, the nanosheet may further include a second portion in a second orientation different from the first orientation. For example, at least one of an upper surface and a lower surface of the second portion may be substantially parallel to the horizontal surface of the substrate. For example, the horizontal surface of the substrate may be one of the {100} crystal plane families, and at least one of the upper surface and the lower surface of the second portion may be one of the {100} crystal plane families. Alternatively, the horizontal surface of the substrate may be one of {110} crystal plane families, and at least one of the upper surface and the lower surface of the second portion may be one of the {110} crystal plane families.

When the nanosheet includes portions in different orientations, the nanosheet may be in a shape of a broken line with one or more inflection points, and the number of the inflection points depends on the number of portions in different orientations. Due to the shape of the broken line, within the same occupied area, the nanosheet may have a larger surface area and thus acquire a greater current drive capability. Also, due to an existence of a portion that is not parallel to the horizontal surface of the substrate, a more mechanical stability may be achieved during manufacturing, which may be beneficial to improve a yield rate.

The nanosheet stack layer may be used as a channel portion, and thus the semiconductor device may become a Multi-Bridge Channel Field Effect Transistor (MBCFET). In this case, the semiconductor device may further include source/drain portions located on two opposite sides of the nanosheet stack layer in the first direction. Each nanosheet in the nanosheet stack layer is connected between the source/drain portions on the two opposite sides, and a conductive channel between the source/drain portions may be formed. The source/drain portions may contain a material that is the same as or different from that of the channel portion to, for example, apply a stress to the channel portion so as to enhance the device performance.

According to the embodiments of the present disclosure, a plurality of devices may be formed on the substrate, and different devices may include nanosheets in different orientations. For example, in a case of a Complementary Metal Oxide Semiconductor (CMOS), an orientation of the nanosheet may be respectively optimized for an n-type device and a p-type device such that, for example, at least a partial surface of at least a portion of the nanosheet of the n-type device is one of the {100} crystal plane families, and at least a partial surface of at least a portion of the nanosheet of the p-type device is one of the {110} crystal plane families, thereby respectively optimizing their performances.

The nanosheet may include a single crystal semiconductor material to improve the device performance. For example, the nanosheet may be formed by an epitaxial growth, so a thickness of the nanosheet may be better controlled and may be substantially uniform. Certainly, the source/drain portions may also contain a single crystal semiconductor material.

According to the embodiments of the present disclosure, a spacing between the nanosheets may be defined by a sacrificial layer. The sacrificial layer may also be formed by an epitaxial growth, so a thickness of the sacrificial layer may be better controlled and may be substantially uniform. Thus, a spacing between adjacent nanosheets may also be substantially uniform.

According to the embodiments of the present disclosure, different first and second devices on the substrate may be formed based on different first and second portions of the same nanosheet stack layer. Thus, the first device and the second device may include similar nanosheet stack layers. For example, the nanosheet stack layer of the first device and the nanosheet stack layer of the second device may have the same number of nanosheets (the number may also be different, for example, one or more nanosheets may be removed for a device in order to adjust the current drive capability). The nanosheet in the first device and the nanosheet in the second device that are located at the same level relative to the substrate may be separated from the same epitaxial layer, and thus may have the same thickness and may contain the same material. Nanosheets at adjacent levels relative to the substrate in the first device and nanosheets at corresponding levels in the second device may be separated by two epitaxial layers at the corresponding levels. Therefore, a spacing between the nanosheets may be determined by the sacrificial layer between the two epitaxial layers and thus may be substantially uniform.

The semiconductor device may further include a gate stack intersecting the channel portion. The gate stack may extend in a second direction intersecting (e.g., perpendicular to) the first direction, and extending across the channel portion from one side of the channel portion to the other side of the channel portion. The gate stack may enter a gap between the nanosheets of the channel portion and a gap between the lowermost nanosheet and the substrate. Thus, the gate stack may surround each nanosheet and define a channel region therein.

A gate spacer may be formed on sidewalls on two opposite sides of the gate stack in the first direction. The gate stack may be separated from the source/drain portions by the gate spacer. Outer sidewalls of the gate spacer facing each source/drain portion may be substantially coplanar in the vertical direction, and may be substantially coplanar with sidewalls of the nanosheets. Inner sidewalls of the gate spacer facing the gate stack may be substantially coplanar in the vertical direction, so that the gate stack may have a substantially uniform gate length. The gate spacer may have a substantially uniform thickness.

Such a semiconductor device may be manufactured, for example, as follows.

In order to form a nanosheet having a surface (which is not parallel to the horizontal surface of the substrate) in the first orientation on the substrate, a pattern having a surface in the first orientation may be formed on the substrate. For example, the pattern may be obtained by patterning the surface of the substrate or a surface of an epitaxial layer on the substrate. On the substrate on which the pattern is formed, a stack layer of alternately arranged sacrificial layers and channel layers may be formed by, for example, an epitaxial growth. At least one of the layers may be substantially conformal to the pattern formed on the substrate, and thus at least a portion of at least one of an upper surface and a lower surface of the layer may be in the first orientation.

The stack layer may be patterned into a stripe shape extending in the first direction. A sacrificial gate layer extending in the second direction intersecting (e.g., perpendicular to) the first direction to intersect the stack layer may be formed on the substrate. The stack layer may be patterned by using a sacrificial gate layer as a mask, so that the stack layer is left below the sacrificial gate layer to form a nanosheet (which may be used as the channel portion). Source/drain portions connected with each nanosheet may be formed by, for example, an epitaxial growth, on two opposite sides of the stack layer in the first direction on the substrate. The sacrificial gate layer and the sacrificial layer in the stack layer may be replaced with a real gate stack by a replacement gate process.

The present disclosure may be presented in various forms, some examples of which will be described below. In the following descriptions, a selection of various materials is involved. In the selection of materials, in addition to a function of the material (for example, a semiconductor material is used for forming an active region, a dielectric material is used for forming an electrical isolation), an etching selectivity is also considered. In the following descriptions, a desired etching selectivity may or may not be indicated. It should be clear to those skilled in the art that when etching a material layer is mentioned below, if it is not mentioned or shown that other layers are also etched, then the etching may be selective, and the material layer may have an etching selectivity relative to other layers exposed to the same etching recipe.

The MBCFET is described below as an example. However, the present disclosure is not limited to this. For example, the nanosheet or the nanosheet stack layer according to the embodiments of the present disclosure may be used in other semiconductor devices.

FIG. 1 to FIG. 20(b) show schematic diagrams of some stages in a process of manufacturing a semiconductor device according to an embodiment of the present disclosure.

As shown in FIG. 1, a substrate 1001 is provided. The substrate 1001 may be a substrate in various forms, including but not limited to a bulk semiconductor material substrate such as a bulk Si substrate, a semiconductor-on-insulator (SOI) substrate, a compound semiconductor substrate such as a SiGe substrate, and the like. In the following descriptions, for ease of explanation, a bulk Si substrate is taken as an example for description.

The substrate 1001 may have a substantially flat top surface. Here, the top surface may be referred to as a horizontal surface of the substrate 1001. For example, the substrate 1001 may be a (100) wafer, so that the horizontal surface of the substrate 1001 may be one of {100} crystal plane families.

A hard mask layer 1005 may be formed by, for example, deposition, on the substrate 1001. For example, the hard mask layer 1005 may contain a nitride (e.g., silicon nitride) with a thickness of about 50 nm to 150 nm. Before the hard mask layer 1005 of nitride is deposited, a thin (e.g., with a thickness of about 2 nm to 10 nm) etch stop layer 1003 of an oxide (e.g., silicon oxide) or other materials may also be formed by, for example, deposition.

In order to form a nanosheet surface inclined relative to the horizontal surface of the substrate 1001 on the substrate 1001, the flat top surface of the substrate 1001 may be patterned to have an inclined configuration. For example, an etching recipe with an etching selectivity for a certain crystal plane orientation may be used to obtain an inclined surface oriented in the crystal plane.

In order to increase a freedom to pattern the surface of the substrate 1001, a more general etching scheme may be used. In this case, in order to better control an inclination, or an orientation of a finally formed inclined surface, a stepped pattern may be formed on the top surface of the substrate 1001, and then a sharp portion of the stepped pattern may be smoothed to form an inclined surface. The inclination may be controlled by controlling a height of a step in the stepped pattern and/or a spacing between adjacent steps. In general, the higher the height of the step, the steeper the step; the smaller the spacing between adjacent steps, the steeper the spacing.

The stepped pattern may be formed in various ways. For example, a portion of the surface of the substrate 1001 may be shielded with a photoresist, and the substrate 1001 may be etched by using the photoresist as a mask. Then, the photoresist is trimmed, and the substrate 1001 is etched by using the trimmed photoresist as a mask. The trimming and etching processes may be repeated a plurality of times, so that the stepped pattern may be obtained.

According to embodiments of the present disclosure, in order to better control the spacing between adjacent steps in the stepped pattern so as to more precisely control the finally obtained inclination, a spacer may be used to facilitate patterning. In order to form the spacer, a mandrel pattern may be formed on the substrate 1001 on which the stepped pattern is required to be formed. For example, as shown in FIG. 2, the hard mask layer 1005 may be selectively etched, such as Reactive Ion Etching (RIE), by using a photoresist (not shown), so as to form the mandrel pattern 1005. Here, the RIE may be in a vertical direction (e.g., a direction substantially perpendicular to the surface of the substrate 1001), so that the mandrel pattern 1005 may have a vertical sidewall. The RIE may be stopped at the etch stop layer 1003.

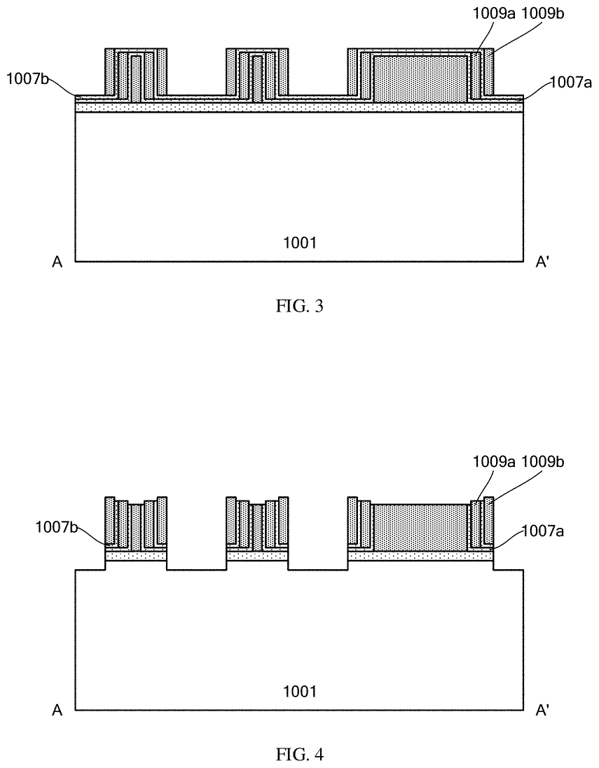

A spacer may be formed on a sidewall of the mandrel pattern 1005. For example, as shown in FIG. 3, spacers 1009a, 1009b may be formed. A formation of the spacer may include substantially conformally forming, for example, depositing, a spacer material layer on the substrate 1001 on which the mandrel pattern 1005 is formed, and performing an anisotropic etching, such as RIE in the vertical direction, on the formed spacer material layer. Here, thicknesses (measured in the horizontal direction in the drawing) of the spacers 1009a, 1009b or a thickness of the deposited spacer material layer may be determined at least partially by an inclination to be achieved. As an example, the thickness of the deposited spacer material layer may be about 3 nm to 20 nm. In addition, in this example, it is shown that two spacers 1009a and 1009b are respectively formed on opposite sidewalls of the mandrel pattern 1005. However, the present disclosure is not limited to this. There may be more or less spacers. Here, the number of spacers 1009a, 1009b may be determined according to the number of steps to be achieved (depending at least partially on a range of an inclined surface to be achieved).

According to the embodiments of the present disclosure, in order to simplify a process, each of the spacers 1009a, 1009b may contain the same material, and may contain the same material as that of the mandrel pattern 1005, such as a nitride. In order to allow etching the spacers one by one in a subsequent process, etch stop layers 1007a, 1007b may be provided between the spacers and between the spacer and the mandrel pattern. For example, the etch stop layers 1007a, 1007b may be thin layers (e.g., with a thickness of about 1 nm to 3 nm), such as oxide layers, with an etching selectivity relative to the spacer and the mandrel pattern. For example, each of the etch stop layers 1007a, 1007b may be deposited before each spacer material layer is deposited.

Next, the substrate 1001 may be etched by using the thus formed mandrel pattern 1005 and spacers 1009a, 1009b so as to form the stepped pattern. The process is similar to the above-mentioned process of repeatedly trimming the photoresist and etching the substrate, except that in each trimming process, a pair of spacers on the opposite sidewalls of the mandrel pattern may be controllably removed.

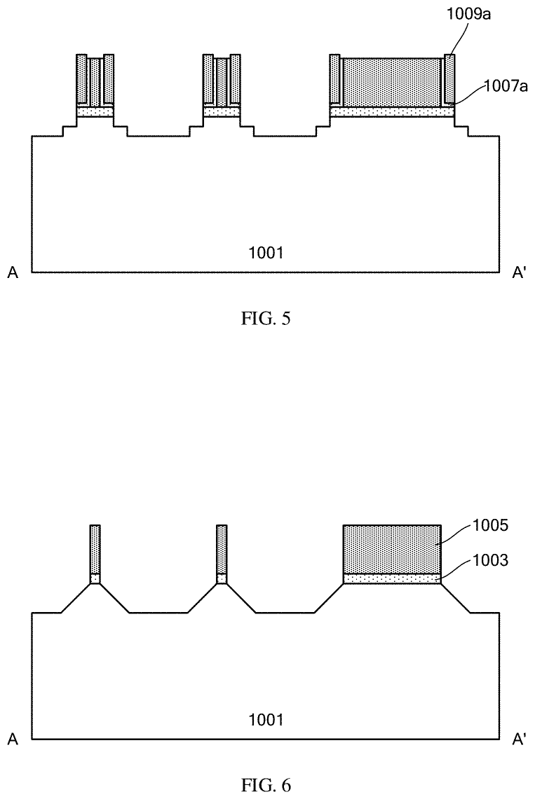

Specifically, as shown in FIG. 4, the etch stop layers 1007b, 1007a, and 1003 may be selectively etched in sequence by, for example, RIE in the vertical direction, so as to expose the surface of the substrate 1001. Then, the exposed portion of the substrate 1001 may be selectively etched to a certain depth by, for example, RIE in the vertical direction. An etching depth (referred to herein as a “first depth”) may be determined according to a height of a step in the stepped pattern to be formed (depending at least partially on an inclination to be achieved). Next, as shown in FIG. 5, the spacer 1009b may be selectively etched isotropically to be removed. The etching of the spacer 1009b may be stopped at the etch stop layer 1007b. The etch stop layers 1007b exposed by a removal of the spacer 1009b, 1007a and the etch stop layer 1003 located below may be selectively etched by, such as RIE, so as to further expose the surface of the substrate 1001. After that, the exposed portion of the substrate 1001 may be selectively etched to a certain depth (herein, referred to as a “second depth”, which may be the same as the first depth) through the process described in combination with FIG. 4. Thus, a current etch depth of the exposed substrate portion in FIG. 4 may be a sum of the first depth plus the second depth, and a current etch depth of a portion of the substrate in FIG. 5 newly exposed by the removal of the spacer 1009b may be the second depth, so that a stepped pattern may be formed. In a similar manner, the spacer 1009a may be further removed and etched again, so that the number of steps may be increased.

Thus, the stepped pattern may be formed on the surface of the substrate 1001. The thus formed stepped pattern may be smoothed to obtain an inclined surface. For example, as shown in FIG. 6, an ion etching and/or bombardment may be performed on the surface of the substrate 1001 to smooth a sharp portion of the stepped pattern, so that an inclined surface may be obtained. The ion etching and/or bombardment may be performed in combination with the RIE process performed on the substrate 1001 after the innermost spacer 1009a is removed. For example, during a process of the RIE performed on substrate 1001, an energy of plasma may be adjusted to achieve a smooth inclined surface (e.g., due to a scattering of Ar or N atoms/ions). The inclination may be controlled by controlling the etch depths, such as the first depth and the second depth, as described in connection with FIG. 4 and FIG. 5, so as to optimize an area occupied by the device and the device performance (e.g., a carrier mobility, an on-current, or the like). As an example, the inclined surface may be one of {110} crystal plane families.

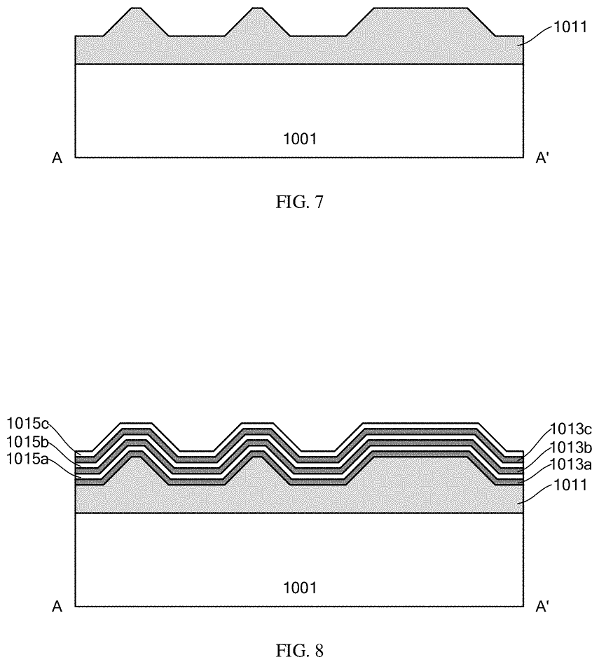

After that, as shown in FIG. 7, the mandrel pattern 1005 and the remaining etch stop layer may be removed by a selective etching. In order to reduce an impact on the surface of the substrate, a wet etching may be used. For example, the mandrel pattern 1005 of nitride may be etched by using a hot phosphoric acid solution, and the etch stop layer of oxide may be etched by using hydrochloric acid or a buffered oxide etchant (BOE).

According to the embodiments of the present disclosure, in order to reduce a leakage between a source and a drain, a well or punch-through stop (PTS) 1011 may be formed in the substrate 1001. For example, a well or PTS 1011 may be formed by implanting a dopant into the substrate 1001 and annealing (e.g., annealing at about 700° C. to 1100° C. for about 0.1 seconds to 1 hour). If an n-type device is to be formed, a p-type dopant such as B, BF2 or In may be implanted; if a p-type device is to be formed, an n-type dopant such as As or P may be implanted.

A doping concentration may be about 1E16 cm⁻³ to 1E19 cm⁻³.

The device may be manufactured on the substrate 1001 having an inclined configuration on the surface of the substrate.

For example, as shown in FIG. 8, an alternating stack layer of sacrificial layers 1013a, 1013b, 1013c and the channel layers 1015a, 1015b, 1015c may be formed on the surface of the substrate 1001 by, for example, an epitaxial growth. The channel layers 1015a, 1015b, 1015c may then form nanosheets of a channel portion, with a thickness of, for example, about 3 nm to 15 nm. When growing the channel layers 1015a, 1015b, 1015c, an in-situ doping may be performed to adjust a device threshold. The sacrificial layers 1013a, 1013b, 1013c may be used to define a gap between the lowermost nanosheet and the substrate 1001, and a gap between adjacent nanosheets, a thickness of the sacrificial layer is, for example, about 5 nm to 20 nm. The number of sacrificial layers and channel layers in the alternating stack layer may be changed according to a device design, for example, may be more or less.

Adjacent layers in the substrate 1001 and the above-mentioned layers formed thereon may have an etching selectivity relative to each other. For example, the sacrificial layers 1013a, 1013b, 1013c may contain SiGe (an atomic percent of Ge is, for example, about 20% to 50%), and the channel layers 1015a, 1015b, 1015c may contain Si.

The channel layers 1015a, 1015b, 1015c may have shapes extending along the surface of the substrate 1001 and thus have surfaces that are inclined or not parallel relative to the horizontal surface of the substrate 1001. For example, the channel layers 1015a, 1015b, 1015c and the sacrificial layers 1013a, 1013b, 1013c may each be formed substantially conformally on the surface of the substrate 1001 and may have a substantially uniform thickness. In this case, the inclined surfaces of the channel layers 1015a, 1015b, 1015c may be consistent with the inclined configuration of the substrate 1001, and thus be, for example, one of the {110} crystal plane families.

The above-mentioned stack layer may be separated into several parts to respectively form channel portions for different devices. For example, as shown in FIG. 9, a photoresist 1017 may be formed on the stack layer and patterned to cover a region where a channel portion is to be formed. Before the photoresist 1017 is formed, a thin oxide layer (not shown) may be formed on a top surface of the stack layer to protect the surface of the stack layer, for example, prevent the surface from being damaged by processes such as oxidation and cleaning during the removal of the photoresist 1017. In this example, three regions covered by the photoresist 1017 (for subsequently forming channel portions of three devices, respectively) are formed. However, the present disclosure is not limited to this. For example, more or less channel portions may be formed. Next, the stack layer may be selectively etched by, such as RIE, by using the photoresist 1017 as a mask, so that the channel portions of different devices are separated from each other. Here, the RIE may proceed into the substrate 1001, in particular under the well or PTS 1011, to form a trench in the substrate 1001, so that an isolation between the devices may then be formed. The trench may be a stripe extending in a first direction (a direction entering a page surface in the drawing), so that the stack layer is divided into stripes extending in the first direction. After that, the photoresist 1017 may be removed.

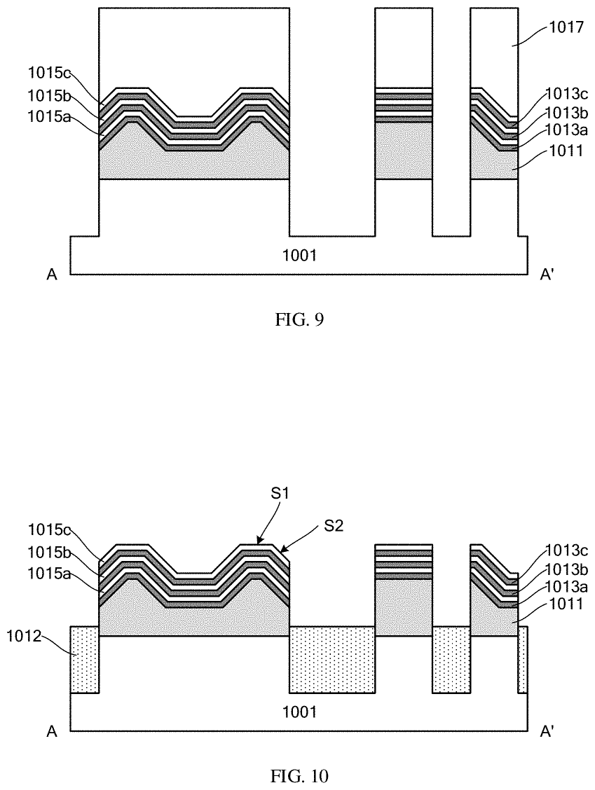

As shown in FIG. 10, an isolation portion 1012 may be formed in the trench of the substrate 1001. For example, an oxide may be deposited on the substrate 1001, and the deposited oxide may fill the formed trench and extend beyond the top surface of the stack layer. A planarization process, such as Chemical Mechanical Polishing (CMP), may be performed on the deposited oxide. Then, the oxide may be etched back such as RIE. During the etching back, a certain thickness of oxide may be left to form the isolation portion 1012. A top surface of the isolation portion 1012 may be higher than a bottom surface of the well or PTS 1011 for an effective isolation, and may be lower than the lowermost surface of the stack layer for a subsequent processing (e.g., the removal of the sacrificial layer) of the stack layer.

As shown in FIG. 10, three device regions are defined. In the leftmost device region, the channel portion may have a surface Si parallel to the horizontal surface of the substrate 1001 and a surface S2 not parallel to the horizontal surface of the substrate 1001, so that the channel portion is in a shape of a broken line. In the rightmost device region, the channel portion may also have a surface parallel to the horizontal surface of the substrate 1001 and a surface not parallel to the horizontal surface of the substrate 1001, so that the channel portion is in a shape of a broken line. It should be noted that, according to a pattern of the photoresist 1017, in the device region, a portion of the channel layer may have a shape of an oblique straight line that is not parallel to the horizontal surface of the substrate 1001 instead of a shape of a broken line. In addition, inflection points of the broken line are not limited to a plurality of inflection points as shown in the drawing, but may be a single inflection point. In a middle device region, the channel portion has a surface parallel to the horizontal surface of the substrate 1001.

As described above, in a case where the substrate 1001 is a (100) wafer, the surface parallel to the horizontal surface of the substrate may be one of {100} crystal plane families, and the surface not parallel to the horizontal surface of the substrate may be one of the {110} crystal plane families. Alternatively, in a case where the substrate 1001 is a (110) wafer, the surface parallel to the horizontal surface of the substrate may be one of the { 110} crystal plane families, and the surface not parallel to the horizontal surface of the substrate may be one of the {100} crystal plane families.

The {100} crystal plane family is beneficial to an electrons mobility. Therefore, a channel portion whose surface is mainly of the {100} crystal plane family (e.g., a middle region in FIG. 10 in a case of the (100) wafer,) may be used to manufacture an n-type device. In addition, the {110} crystal plane family is beneficial to a hole mobility. Therefore, a channel portion whose surface is mainly of the {110} crystal plane family (e.g., the rightmost region in FIG. 10 in a case of the (100) wafer,) may be used to manufacture a p-type device. The leftmost region in FIG. 10 has surfaces of both the {100} crystal plane family and the {110} crystal plane family, so a p-type device or an n-type device may be manufactured.

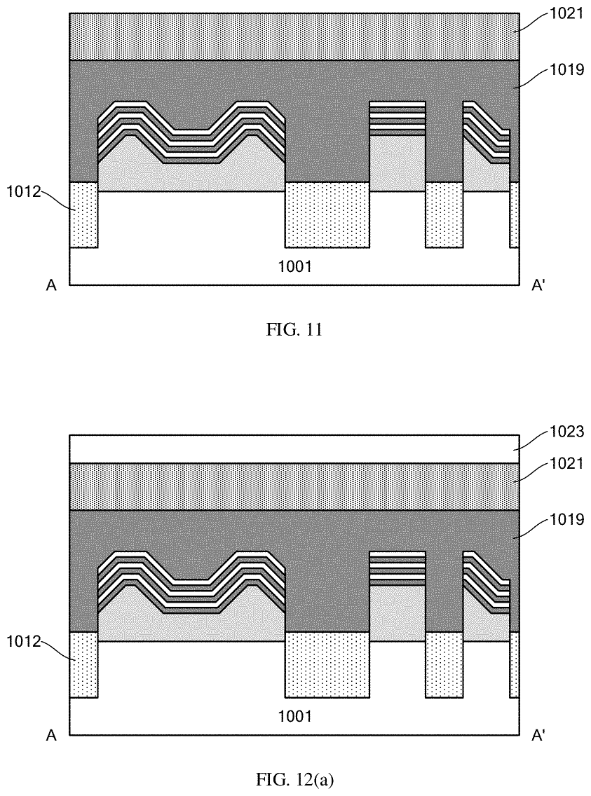

As shown in FIG. 11, a sacrificial gate layer 1019 may be formed on the isolation layer 1012. The sacrificial gate layer 1019 may contain a material similar to or the same as that of the sacrificial layers 1013a, 1013b, 1013c, so that the sacrificial gate layer 1019 may be subsequently etched by the same etching recipe. For example, the sacrificial gate layer 1019 may contain SiGe with an atomic percentage of Ge of about 20% to 50%, which is substantially the same as or close to that in the sacrificial layers 1013a, 1013b, 1013c. The sacrificial gate layer 1019 may be formed by deposition and then planarization such as CMP. A hard mask layer 1021 may be formed by, for example, deposition, on the sacrificial gate layer 1019, so as to facilitate a subsequent patterning of the sacrificial gate layer 1019. For example, the hard mask layer 1021 may contain a nitride.

The sacrificial gate layer 1019 may be patterned into a stripe extending in a second direction (a horizontal direction on the paper surface in the drawing) intersecting (e.g., perpendicular to) the first direction, so that a sacrificial gate is formed. For example, as shown in FIG. 12(a) and FIG. 12(b), a photoresist 1023 may be formed on the hard mask layer 1021 and patterned into a stripe extending in the second direction (see a top view in FIG. 12(b)). Then, as shown in FIG. 13(a) and FIG. 13(b), the hard mask layer 1021 and the sacrificial gate layer 1019 are sequentially selectively etched by, for example, RIE, by using the photoresist 1023 as a mask. Thus, the sacrificial gate layer 1019 is patterned into a stripe extending in the second direction. In addition, the channel layers and the sacrificial layers exposed by a removal of the sacrificial gate layer 1019 in the stack layer may also be selectively etched in sequence by, for example, RIE, so that the stack layer is left below the sacrificial gate layer 1019. The etching may be stopped at the isolation portion 1012 of an oxide. After that, the photoresist 1023 may be removed.

As shown in FIG. 13(a), the current sacrificial gate layer 1019 and the sacrificial layers 1013a, 1013b, 1013c surround the channel layers 1015a, 1015b, 1015c, and the current sacrificial gate layer 1019 and the sacrificial layers 1013a, 1013b, 1013c define a space subsequently used for the gate stack.

Gate spacers may be formed on sidewalls of the sacrificial gate layer 1019 and the sacrificial layers 1013a, 1013b, and 1013c. For example, as shown in FIG. 14, the sacrificial gate layer 1019 and the sacrificial layers 1013a, 1013b, and 1013c may be recessed by a certain depth of, for example, about 2 nm to 7 nm (relative to the channel layers 1015a, 1015b, and 1015c) by selective etching. In order to control a recessed depth, an Atomic Layer Etching (ALE) may be used. A dielectric material may be filled in the recesses thus formed to form the gate spacers 1025. The filling may be formed by, for example, depositing a nitride with a thickness of about 3 nm to 10 nm and then performing RIE on the deposited nitride (until the surface of the channel layer is exposed). Here, the hard mask layer 1021 which is also a nitride may be integrated with the gate spacers on the sidewalls of the sacrificial gate layer 1019, and may thus be marked as 1021′.

According to the process, the gate spacers 1025 may be self-aligned to be formed on the sidewalls of the sacrificial gate layer 1019 and the sacrificial layers 1013a, 1013b, 1013c, but not on sidewalls of the channel layers 1015a, 1015b, 1015c. The gate spacer 1025 may have a substantially uniform thickness which, for example, depends on a depth of the above-mentioned recess. In addition, outer sidewall of the gate spacers 1025 may be substantially vertically aligned with outer sidewalls of the channel layers 1015a, 1015b, 1015c, and inner sidewalls of the gate spacers 1025 may be substantially vertically aligned (by controlling the etch depth at each position to be substantially the same when forming the recess).

After that, source/drain portions connected to the sidewalls of the channel layers 1015a, 1015b, and 1015c may be formed on two sides of the sacrificial gate layer 1019.

As shown in FIG. 15, source/drain portions 1027 may be formed by, for example, an epitaxial growth. The source/drain portions 1027 may be grown from an exposed surface of the substrate 1001 and surfaces of the channel layers 1015a, 1015b, 1015c. The grown source/drain portions 1027 are connected with the sidewalls of the channel layers 1015a, 1015b, and 1015c. During the growth, the source/drain portions 1027 may be doped in situ to a conductivity type corresponding to the device to be formed, e.g., an n-type for an n-type device and a p-type for a p-type device, and a doping concentration may be about 1E19 cm ⁻³ to 1E21 cm⁻³. The grown source/drain portion 1027 may contain a material different (e.g., having a different lattice constant) from the channel layer, so as to apply a stress to the channel layer. For example, for an n-type device, the source/drain portion 1027 may contain Si:C (an atomic percent of C is, for example, about 0.1% to 5%); for a p-type device, the source/drain portion 1027 may contain SiGe (an atomic percent of Ge is, for example, about 20% to 75%). When the n-type device and the p-type device are simultaneously formed on the substrate, for example, in a case of a CMOS process, source/drain portions may be respectively grown for the n-type device and the p-type device. When a source/drain portion of one type of device is grown, a region of another type of device may be shielded by a shielding layer such as a photoresist or the like.

Next, a replacement gate process may be performed to complete a device manufacturing.

For example, as shown in FIG. 16(a) and FIG. 16(b), a dielectric material 1031 such as an oxide may be deposited on the substrate 1001, so as to cover the sacrificial gate layer 1019, the source/drain portion 1027 and the isolation portion 1012. A planarization process such as CMP may be performed on the dielectric material 1031 to expose the sacrificial gate layer 1019.

The sacrificial gate layer 1019 and the sacrificial layers 1013a, 1013b, 1013c may be removed by a selective etching (as described above, they may be etched by the same etching recipe), so that a space may be formed inside the gate spacer 1025, and a gate stack 1029 may be formed in the space. For example, a gate dielectric layer 1029a and a gate conductor layer 1029b may be sequentially formed (see FIG. 17(a) and FIG. 17(b)). The gate dielectric layer 1029a may be formed in a substantially conformal manner, with a thickness of, for example, about 2 nm to 5 nm, and may include a high-k gate dielectric such as HfO2. Before the high-k gate dielectric is formed, an interface layer, e.g., an oxide formed by an oxidation process or deposition such as an Atomic Layer Deposition (ALD), may also be formed on the surface of the channel layer, with a thickness of about 0.2 nm to 2 nm. The gate conductor layer 1029b may contain a work function adjustment metal such as TiN, TaN, etc. and a gate conductive metal such as W, etc. When the n-type device and the p-type device are simultaneously formed on the substrate, for example, in a case of a CMOS process, different gate stacks may be respectively formed for the n-type device and the p-type device. For example, after a first gate stack for one type of device is formed, a region of the type of device may be shielded by a shielding layer such as a photoresist. A first gate stack existing in a region of another type of device may be removed (only the gate conductor layer may be removed), and then a second gate stack for the another type of device may be formed.

FIG. 17(a) and FIG. 17(b) more clearly show portions of gate stacks around the channel layers in an enlarged form. It may be shown that the gate stacks are located on an inner side of the gate spacer 1025 and surrounding each of the channel layers 1015a, 1015b and 1015c. The channel layers 1015a, 1015b, and 1015c are connected to the source/drain portions 1027 on the two sides, respectively, and channels are formed between the source/drain portions 1027.

According to the embodiments of the present disclosure, the channel layers 1015a, 1015b, 1015c are more mechanically stable due to an existence of the channel layers with an inclined portion, e.g., are not easily bent or adhered during the removal of the sacrificial layers 1013a, 1013b, 1013c, which is beneficial to improve a yield rate.

Currently, one same source/drain portion 1027 is connected to the channel layers 1015a, 1015b, 1015c on two opposite sides. That is, devices on the two sides are now electrically connected together. An electrical isolation may be performed between the devices according to a design layout.

The electrical isolation may be performed prior to the replacement gate process. For example, as shown in FIG. 18, after the dielectric material 1031 is formed and planarized as described above to expose the sacrificial gate layer 1019, a photoresist 1033 may be formed on the dielectric material 1031 and patterned to shield one or more sacrificial gate layers 1019, while other sacrificial gate layers 1019 are exposed. In the example of FIG. 18, the sacrificial gate layer 1019 in the middle is shielded, while the sacrificial gate layers 1019 on the two sides are exposed. The exposed sacrificial gate layer 1019 and the channel layer and the sacrificial layer located below may be selectively etched in sequence by, for example, RIE, thereby leaving a space between the gate spacers 1025. The etching may proceed into the well or PTS 1011 to achieve a good electrical isolation. After that, the photoresist 1033 may be removed. A dielectric material 1035 such as an oxide, may be filled in the space left. The filling of the dielectric material 1035 may include deposition and then planarization. After that, the above-mentioned replacement gate process may be performed to form the gate stack 1029, so that structures shown in a left portion of FIG. 19(a) and FIG. 19(b) may be acquired.

According to other embodiments of the present disclosure, a plurality of dielectric layers may be formed in the above-mentioned space by, for example, a sequential deposition. For example, as shown in a right portion of FIG. 19(a), a stacked structure of multilayer dielectrics 1035-1, 1035-2, 1035-3 may be formed. According to the embodiment, the dielectric layer 1035-1 may contain an oxide, the dielectric layer 1035-2 may contain a nitride, and the dielectric layer 1035-3 may contain an oxynitride. However, the present disclosure is not limited to this. For example, more or fewer dielectric layers may be formed, and the dielectric layers may contain other materials.

Alternatively, the electrical isolation may also be performed after the replacement gate process. For example, after the above-mentioned replacement gate process is performed, a photoresist may be similarly formed to shield one or more gate stacks 1029 while exposing other gate stacks 1029. The exposed gate stacks and material layers located below may be removed by a selective etching to leave the above-mentioned space which may be filled with a dielectric material.

In addition, as shown in FIG. 19(b), the current gate stack 1029 extends continuously between device regions, so that respective gates of the devices are electrically connected to each other. An electrical isolation may be achieved between the devices according to a design layout.

For example, as shown in FIG. 20(a) and FIG. 20(b), a photoresist (not shown) may be formed on the dielectric material 1031 to expose the gate stack 1029 between the device regions to be isolated, while shielding other gate stacks 1029. After that, a selective etching such as RIE may be performed on the exposed gate stack 1029 (especially the gate conductor layer 1029b therein). The etching may be stopped at the isolation portion 1012 located below (or stopped at the gate dielectric layer 1029a). A dielectric material 1037 such as an oxide may be filled in a space left by an etching of the exposed portion of the gate stack 1029. The filling of the dielectric material 1037 may include deposition and then planarization.

It should be noted here that FIG. 20(a) and FIG. 20(b) show cases where an isolation process described with reference to FIG. 18 to FIG. 19(b) is not performed. The isolation process described with reference to FIG. 20(a) and FIG. 20(b) may also be performed similarly to the cases shown in FIG. 19(a) and FIG. 19(b). Whether the isolation processes are performed depends on whether an electrical connection or electrical isolation is required between adjacent devices in a design layout.

FIG. 21 shows a schematic diagram of a CMOS configuration according to the embodiments of the present disclosure.

As described above, in a case of the CMOS, different gate stacks may be formed for an n-type device and a p-type device, respectively. For example, as shown in FIG. 21, when p-type devices are formed in device regions on the two sides and an n-type device is formed in a device region in the middle, p-type gate stacks 1029p and an n-type gate stack 1029n may be respectively formed for the p-type device and the n-type device, for example, each of them has a different work function.

In the above-mentioned embodiments, a leakage may be suppressed by the well or PTS 1011. However, the embodiments of the present disclosure are not limited to this. For example, an isolation portion may be formed below the channel portion to suppress a leakage between the source and the drain.

FIG. 22 to FIG. 30 show schematic diagrams of some stages in a process of manufacturing a semiconductor device according to another embodiment of the present disclosure. Differences from the above-mentioned embodiments will be mainly described below.

A substrate 1001 may be provided as described above with reference to FIG. 1. A position defining layer 1002 and a position maintaining layer 1004 may be sequentially formed by, for example, an epitaxial growth on the substrate 1001. The position defining layer 1002 may be used to define a bottom position of an isolation portion in a subsequent etch, with a thickness of, for example, about 5 nm to 20 nm; the position defining layer 1004 may be used to define a space occupied by the isolation portion, with a thickness of, for example, about 20 nm to 150 nm. Adjacent layers of the substrate 1001, the position defining layer 1002, and the position maintaining layer 1004 may have an etching selectivity relative to each other. For example, the substrate 1001 may be a silicon wafer, the position defining layer 1002 may contain SiGe (an atomic percentage of Ge is, for example, about 20% to 50%), and the position maintaining layer 1004 may contain Si. In this example, both the substrate 1001 and the position maintaining layer 1004 contain Si, so that in the following, the position defining layer 1002 may be used to define an etch stop position when the position maintaining layer 1004 is selectively etched. However, the present disclosure is not limited to this. For example, the position defining layer 1002 may also be omitted when the substrate 1001 and the position maintaining layer 1004 contain materials having an etching selectivity relative to each other.

The processes described above with reference to FIG. 1 to FIG. 8 may be performed, so that an inclined configuration may be formed on a surface of the position maintaining layer 1004 and an alternating stack layer of sacrificial layers 1013a, 1013b, 1013c and channel layers 1015a, 1015b, 1015c may be formed.

An isolation portion may be formed by replacing the position maintaining layer 1004 with a dielectric material. During the replacement, a process in which the stack layer is suspended relative to the substrate exists. In order to maintain the stack layer, a support portion that is connected to the substrate may be formed. For the same device region, a support portion may be formed on one side, while the other side may be exposed for the replacement process. Adjacent device regions may share a support portion located therebetween. Here, forming three devices similar to those in the above-mentioned embodiments is taken an example for description. In this case, two support portions may be formed.

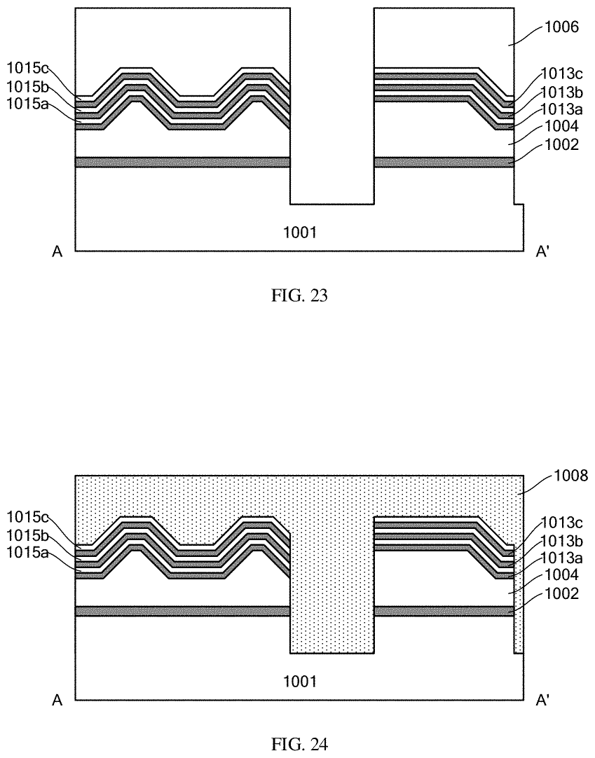

For example, as shown in FIG. 23, a photoresist 1006 may be formed on the stack layer and patterned to expose a region (a region between adjacent device regions) where a support portion is to be formed. Before the photoresist 1006 is formed, a thin oxide layer (not shown) may be formed on a top surface of the stack layer to protect a surface of the stack layer. The stack layer may be selectively etched such as RIE, by using the photoresist 1006 as a mask. The RIE may proceed into the substrate 1001 to form a support portion trench, so that the subsequently formed support portion may be connected to the substrate 1001. After that, the photoresist 1006 may be removed.

As shown in FIG. 24, a dielectric material 1008, such as an oxide, may be formed on the substrate 1001 by, for example, deposition. The dielectric material 1008 may be used to fill the support portion trench and cover the stack layer. A planarization process such as CMP may be performed on the deposited dielectric material 1008. The dielectric material 1008 filled in the support portion trench may be used to form the support portion.

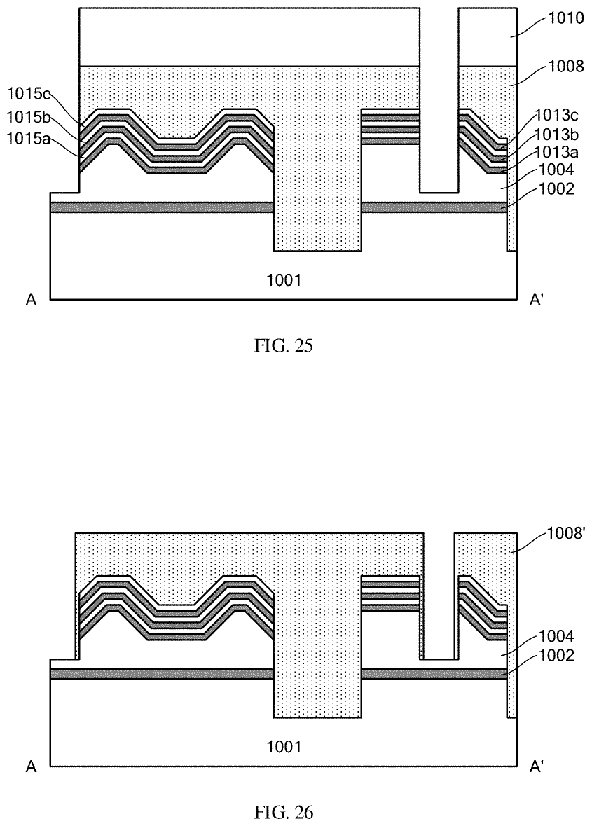

In addition, the stack layer may be separated between different device regions. In this example, due to a formation of the support portion, each device region has been separated from an adjacent device region on one side, thus it is only required to be separated on the other side. For example, as shown in FIG. 25, a photoresist 1010 may be formed on the dielectric material 1008 and patterned to expose a region between adjacent device regions (there is no need to expose a position where the support portion has been formed). The stack layer may be selectively etched such as RIE, by using the photoresist 1010 as a mask to form an isolation trench, so that channel portions of different devices are separated from each other. Here, the RIE may proceed into the position maintaining layer 1004, but not reaching the position defining layer 1002 (which may avoid that the position maintaining layer 1004 may not be replaced due to being completely obscured by a protective layer in a case of forming the protective layer below). After that, the photoresist 1010 may be removed.

Next, the position maintaining layer 1004 may be replaced with an insulator. In order to protect the stack layer, especially the channel layer therein (especially in this example, both the channel layer and the position maintaining layer 1004 contain Si), during a removal of the position maintaining layer 1004, a protective layer may be formed on a sidewall of the stack layer. For example, as shown in FIG. 26, a protective layer may be formed on an exposed sidewall of the stack layer through a spacer forming process. In this example, the protective layer may contain an oxide, and may thus be shown as 1008′ integrally with the dielectric material 1008, which is also an oxide.

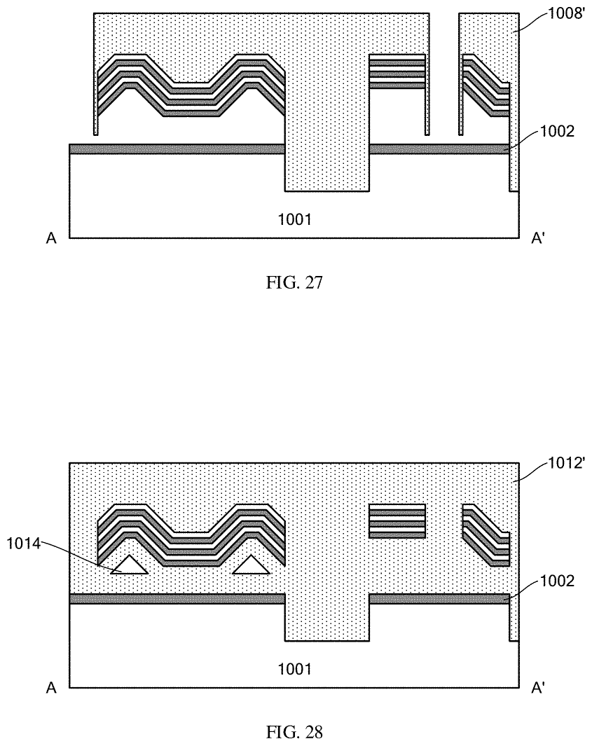

As shown in FIG. 27, the position maintaining layer 1004 may be removed by a selective etching. On one hand, the support portion may suspend the stack layer relative to the substrate 1001; on the other hand, the isolation trench may form a processing channel for etching the position maintaining layer 1004 below the stack layer. For example, the position maintaining layer 1004 (Si in this example) may be selectively etched relative to the support portion (oxide in this example) and the position defining layer 1002 and sacrificial layer 1013a (SiGe in this example) by using a TMAH solution.

As shown in FIG. 28, a dielectric material may be filled below the stack layer through the isolation trench to form an isolation portion. The filling may be performed by deposition such as a Chemical Vapor Deposition (CVD), an Atomic Layer Deposition (ALD), and the like. Depending on a size of a space below the stack layer and a filling performance of the deposition process, the dielectric material may not be completely filled below the stack layer, and an air gap 1014 may exist. In order to improve the filling performance, a method of repeating deposition and etching may be used. In addition, the isolation trench may also be filled with a dielectric material to form an isolation portion between devices. The filled dielectric material may contain an oxide, and may thus be shown as 1012′ with the above-mentioned dielectric material 1008′.

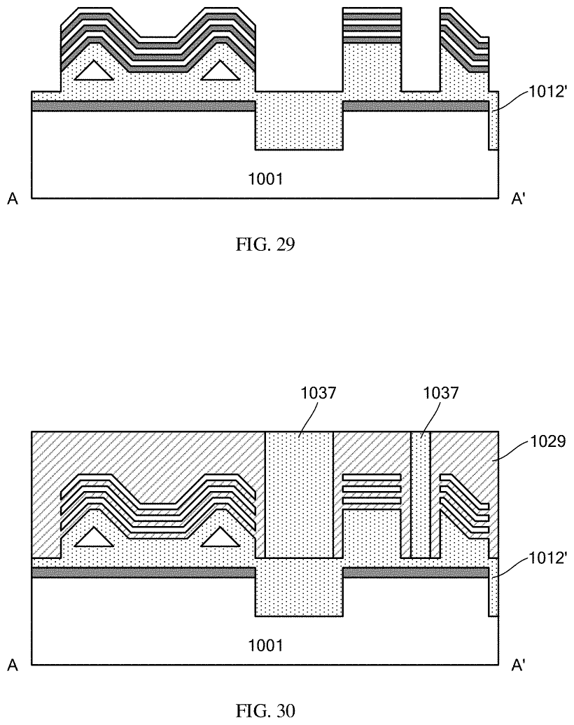

As shown in FIG. 29, the dielectric material 1012′ may be etched back to form an isolation portion. A top surface of the dielectric material 1012′ that has been etched back may be higher than the position defining layer 1002 for an effective isolation, and may be lower than the lowermost surface of the stack layer for a subsequent processing (e.g., a removal of the sacrificial layer) of the stack layer. It may be shown that, on the one hand, the isolation portion 1012′ is disposed between adjacent devices to form an electrical isolation such as a STI (Shallow Trench Isolation) between the adjacent devices, on the other hand, the isolation portion 1012′ is disposed below the channel portion to suppress a leakage between the source and the drain in the same device.

After that, the semiconductor device shown in FIG. 30 may be obtained by the processes described above with reference to FIG. 11 to FIG. 20(b).

The semiconductor device according to the embodiments of the present disclosure may be applied to various electronic apparatuses. For example, an integrated circuit (IC) may be formed based on the semiconductor device, and thus an electronic apparatus may be constructed. Accordingly, the present disclosure further provides an electronic apparatus including the above-mentioned semiconductor device. The electronic apparatus may further include a display screen cooperating with the integrated circuit, a wireless transceiver cooperating with the integrated circuit, and other components. The electronic apparatus may include, for example, a smart phone, a computer, a Personal Computer (PC), an artificial intelligence apparatus, a wearable apparatus, a mobile power supply, etc.

According to the embodiments of the present disclosure, there is further provided a method of manufacturing a System on Chip (SoC). The method may include the above-mentioned method. In particular, a variety of devices may be integrated on a chip, at least some of which are manufactured according to the method of the present disclosure.

In the above descriptions, technical details such as patterning and etching of each layer have not been described in detail. However, those skilled in the art should understand that various technical means may be used to form layers, regions, etc. of desired shapes. In addition, in order to form the same structure, those skilled in the art may further design a method that is not exactly the same as the method described above. In addition, although the various embodiments have been described above respectively, this does not mean that the measures in the various embodiments may not be advantageously used in combination.

The embodiments of the present disclosure have been described above. However, these examples are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should all fall within the scope of the present disclosure.

1. A semiconductor device comprising:
a nanosheet stack layer on a substrate comprising a plurality of nanosheets spaced apart from each other in a vertical direction relative to the substrate, wherein at least one nanosheet of the plurality of nanosheets comprises a first portion in a first orientation, and at least one of an upper surface and or a lower surface of the first portion is not parallel to a horizontal surface of the substrate.

2. The semiconductor device according to claim 1, wherein the at least one nanosheet further comprises a second portion in a second orientation different from the first orientation.

3. The semiconductor device according to claim 1, wherein the horizontal surface of the substrate is one of { 100} crystal plane families, and the at least one of the upper surface or the lower surface of the first portion is one of {110} crystal plane families; or
the horizontal surface of the substrate is one of {110} crystal plane families, and the at least one of the upper surface or the lower surface of the first portion is one of { 100} crystal plane families.

4. The semiconductor device according to claim 2, wherein
the horizontal surface of the substrate is one of {100} crystal plane families, the at least one of the upper surface or the lower surface of the first portion is one of {110} crystal plane families, and at least one of an upper surface or a lower surface of the second portion is one of the {100} crystal plane families; or
the horizontal surface of the substrate is one of {110} crystal plane families, the at least one of the upper surface or the lower surface of the first portion is one of { 100} crystal plane families, and at least one of an upper surface or a lower surface of the second portion is one of the {110} crystal plane families.

5. The semiconductor device according to claim 1, wherein a spacing distance between adjacent nanosheets of the plurality of nanosheets is substantially uniform.

6. The semiconductor device according to claim 1, wherein the at least one nanosheet of the plurality of nanosheets is in a shape of a broken line with one or more inflection points.

7. The semiconductor device according to claim 1, further comprising:
source/drain portions on the substrate located on two opposite sides of the nanosheet stack layer in a first direction and connected with the nanosheets in the nanosheet stack layer; and
a gate stack on the substrate extending in a second direction and overlapping the nanosheets, wherein the second direction intersects the first direction.

8. The semiconductor device according to claim 7, wherein the gate stack is disposed between the nanosheet stack layer and the substrate, between the nanosheets in the nanosheet stack layer, and above the nanosheet stack layer.

9. The semiconductor device according to claim 8, further comprising a dielectric layer disposed between the gate stack and the substrate.

10. The semiconductor device according to claim 9, wherein the dielectric layer comprises an air gap.

11. The semiconductor device according to claim 8, further comprising: a gate spacer disposed on a sidewall of the gate stack, wherein the gate spacer comprises a first portion above a respective nanosheet and a second portion below the respective nanosheet.

12. The semiconductor device according to claim 11, wherein the first portion of the gate spacer has a thickness substantially the same as a thickness of the second portion of the gate spacer.

13. The semiconductor device according to claim 11, wherein an inner sidewall of the first portion of the gate spacer and an inner sidewall of the second portion of the gate spacer are substantially aligned in the vertical direction.

14. The semiconductor device according to claim 11, wherein an outer sidewall of the gate spacer is substantially aligned with an outer sidewall of the respective nanosheet in the nanosheet stack layer in the vertical direction.

15. The semiconductor device according to claim 11, wherein
a plurality of the semiconductor devices are provided on the substrate, and semiconductor devices adjacent in the first direction in the plurality of the semiconductor devices are electrically isolated from each other by an isolation portion, wherein a range of the isolation portion in the first direction is defined by a dummy gate spacer extending in the second direction.

16. The semiconductor device according to claim 15, wherein a range of a top portion of the source/drain portion of the semiconductor device in the first direction is defined by the gate spacer of the semiconductor device and the dummy gate spacer.

17. The semiconductor device according to claim 7, wherein
a plurality of the semiconductor devices are provided on the substrate, and semiconductor devices adjacent in the first direction in the plurality of the semiconductor devices are electrically isolated from each other by an isolation portion, wherein the isolation portion extends in the second direction.

18. The semiconductor device according to claim 17, wherein the source/drain portion extends in the second direction, and
the semiconductor device further comprises: a gate spacer located between the gate stack and the source/drain portion and a dummy gate spacer located between the source/drain portion and the isolation portion, wherein the gate spacer has a thickness substantially the same as a thickness of the dummy gate spacer in the first direction.

19. The semiconductor device according to claim 18, wherein the gate spacer contains a material the same as a material of the dummy gate spacer.

20. The semiconductor device according to claim 17, wherein the isolation portion contains a multilayer dielectric material.

21. The semiconductor device according to claim 15 or 18, further comprising: a semiconductor layer aligned with the dummy gate spacer in the vertical direction and corresponding to the respective nanosheet in the nanosheet stack layer.

22. A semiconductor device, comprising:
a first device and a second device on a substrate, wherein the first device comprises a plurality of first nanosheets stacked and spaced apart from each other in a vertical direction relative to the substrate, and the second device comprises a plurality of second nanosheets stacked and spaced apart from each other in the vertical direction relative to the substrate,
wherein at least one of the first nanosheets comprises a first portion in a first orientation, and at least one of the second nanosheets comprises a second portion in a second orientation different from the first orientation.

23. The semiconductor device according to claim 22, wherein
a horizontal surface of the substrate is one of {100} crystal plane families, at least one of an upper surface or a lower surface of the first portion is one of {110} crystal plane families, and at least one of an upper surface or a lower surface of the second portion is one of the {100} crystal plane families; or
a horizontal surface of the substrate is one of {110} crystal plane families, at least one of an upper surface or a lower surface of the first portion is one of {100} crystal plane families, and at least one of an upper surface or a lower surface of the second portion is one of the {110} crystal plane families.

24. The semiconductor device according to claim 22, wherein a spacing distance between adjacent nanosheets in the first nanosheets is substantially uniform, and a spacing distance between adjacent nanosheets in the second nanosheets is substantially uniform;
wherein the first nanosheet and the second nanosheet that are located at a same level relative to the substrate contain substantially a same material and have substantially a same thickness;
wherein a distance between the first nanosheets at adjacent levels relative to the substrate is substantially the same as a distance between the second nanosheets at corresponding adjacent levels.

25-26. (canceled)

27. The semiconductor device according to claim 22, further comprising:
first source/drain portions located on two opposite sides of the plurality of first nanosheets in a first direction and connected with the first nanosheets;
a first gate stack on the substrate extending in a second direction and overlapping the first nanosheets, wherein the second direction intersects the first direction;
second source/drain portions located on two opposite sides of the plurality of second nanosheets in the first direction and connected with the second nanosheets; and
a second gate stack on the substrate extending in the second direction and overlapping the second nanosheets.

28. The semiconductor device according to claim 27, wherein
the first gate stack is aligned with the second gate stack in the second direction, and
the first nanosheet is aligned with the second nanosheet in the second direction.

29. The semiconductor device according to claim 28, further comprising:
a gate spacer extending continuously on a sidewall of the first gate stack, on a sidewall of the second gate stack, and between the first gate stack and the second gate stack.

30. The semiconductor device according to claim 27, further comprising a dielectric layer disposed between at least one of the first gate stack and the second gate stack and the substrate.

31. The semiconductor device according to claim 30, wherein the dielectric layer comprises an air gap.

32. A method of manufacturing a semiconductor device, comprising:
forming a pattern on a substrate, wherein the pattern comprises at least a first surface in a first orientation, wherein the first surface is not parallel to a horizontal surface of the substrate; and
forming a stack layer of alternately arranged sacrificial layers and channel layers on the substrate having the pattern, wherein at least a portion of at least one of an upper surface and a lower surface of at least one of the channel layers is in the first orientation.

33. The method according to claim 32, further comprising:
patterning the stack layer into a stripe extending in a first direction;
forming a sacrificial gate layer extending in a second direction on the stack layer, wherein the second direction intersects the first direction;
selectively etching the stack layer by using the sacrificial gate layer as a mask;
forming, on two opposite sides of the stack layer in the first direction on the substrate, semiconductor layers for forming source/drain portions; and
replacing the sacrificial gate layer and the sacrificial layer in the stack layer with a gate stack.

34. The method according to claim 32, wherein the pattern further comprises a second surface having a second orientation different from the first orientation.

35. The method according to claim 32, wherein
the horizontal surface of the substrate is one of { 100} crystal plane families, and the first orientation is one of {110} crystal plane families; or
the horizontal surface of the substrate is one of {110} crystal plane families, and the first orientation is one of { 100} crystal plane families.

36. The method according to claim 34, wherein
the horizontal surface of the substrate is one of { 100} crystal plane families, the first orientation is one of {110} crystal plane families, and the second orientation is one of the {100} crystal plane families; or
the horizontal surface of the substrate is one of { 110} crystal plane families, the first orientation is one of {100} crystal plane families, and the second orientation is one of the {110} crystal plane families.

37. The method according to claim 32, wherein the forming a pattern comprises:
forming a stepped pattern on the substrate by etching a surface of the substrate; and
performing an ion etching on the surface of the substrate having the stepped pattern, so as to form an inclined surface on the surface of the substrate.

38. The method according to claim 37, wherein the forming a stepped pattern comprises:
forming a mandrel pattern on the surface of the substrate;
forming at least one pair of etch stop layer and spacer layer on a sidewall of the mandrel pattern;
etching the substrate by using the mandrel pattern and the etch stop layer and the spacer layer on the sidewall of the mandrel pattern as a mask;
removing a pair of etch stop layer and spacer layer on an outermost side, and etching the substrate by using the mandrel pattern and the etch stop layer and the spacer layer left on the sidewall of the mandrel pattern as a mask; and
repeating the steps of removing and etching until all of the etch stop layers and the spacer layers are removed.

39. The method according to claim 33, further comprising:
forming a position defining layer on the substrate;
forming a position maintaining layer on the position defining layer, wherein the pattern is formed on the position maintaining layer,
wherein the patterning the stack layer into a stripe extending in a first direction comprises:
forming a stripe-shaped support portion trench extending in the first direction in the stack layer;
forming a support portion for supporting the stack layer in the support portion trench;
forming a stripe-shaped isolation trench extending in the first direction in the stack layer;
removing the position maintaining layer through the isolation trench; and
at least partially filling, through the isolation trench, a dielectric material in a space left below the stack layer by a removal of the position maintaining layer.

40. An electronic apparatus comprising the semiconductor device according to claim 1, wherein the electronic apparatus comprises a smartphone, a computer, a tablet computer, an artificial intelligence apparatus, a wearable apparatus, or a mobile power supply.

41. (canceled)
